(19) United States
(12) Patent Application Publication
(10) Pub. No.: US 2017/0271734 A1
(43) Pub. Date: Sep. 21, 2017

(54) EMBEDDED CAVITY IN PRINTED CIRCUIT BOARD BY SOLDER MASK DAM

(71) Applicant: Multek Technologies Limited, San Jose, CA (US)

(72) Inventors: Pui Yin Yu, Tsuen Wan (HK); Jiawen Chen, Guangdong (CN)

(73) Assignee: Multek Technologies Limited, San Jose, CA (US)

(21) Appl. No.: 15/087,793

(22) Filed: Mar. 31, 2016

(30) Foreign Application Priority Data
Mar. 17, 2016 (CN) 201610154210.5

(51) Int. Cl. H01P 3/08; H05K 3/06; H05K 3/46; H05K 3/42; H05K 1/02; H05K 1/11

(52) U.S. Cl. CPC H01P 3/08; H05K 1/0298; H05K 1/115; H05K 3/4652; H05K 3/422; H05K 3/4697; H05K 3/06; H05K 2201/09036

(57) ABSTRACT

A PCB having multiple stacked layers laminated together. The laminated stack includes regular flow prepreg and includes an embedded cavity, the perimeter of which is formed by a photo definable, or photo imageable, polymer structure, such as a solder mask dam. The solder mask dam defines cavity dimensions and prevents prepreg resin flow into the cavity during lamination.

### CROSS-REFERENCE TO RELATED APPLICATION(S)

This application claims priority under 35 U.S.C. §119(a)-(d) of the Chinese Patent Application No: 201610154210.5, filed Mar. 17, 2016 and titled, “EMBEDDED CAVITY IN PRINTED CIRCUIT BOARD BY SOLDER MASK DAM,” which is hereby incorporated by reference in its entirety for all purposes.

### FIELD OF THE INVENTION

The present invention is generally directed to printed circuit boards. More specifically, the present invention is directed to printed circuit boards having embedded cavities.

### BACKGROUND OF THE INVENTION

A printed circuit board (PCB) mechanically supports and electrically connects electronic components using conductive traces, pads and other features etched from electrically conductive sheets, such as copper sheets, laminated onto a non-conductive substrate. Multi-layered printed circuit boards are formed by stacking and laminating multiple such etched conductive sheet/non-conductive substrate. Conductors on different layers are interconnected with plated-through holes called vias.

A printed circuit board includes a plurality of stacked layers, the layers made of alternating non-conductive layers and conductive layers. The non-conductive layers can be made of prepreg or base material that is part of a core structure, or simply core. Prepreg is a fibrous reinforcement material impregnated or coated with a resin binder, and consolidated and cured to an intermediate stage semi-solid product. Prepreg is used as an adhesive layer to bond discrete layers of multilayer PCB construction, where a multilayer PCB consists of alternative layers of conductors and base materials bonded together, including at least one internal conductive layer. A base material is an organic or inorganic material used to support a pattern of conductor material. A core is a metal clad base material where the base material has integral metal conductor material on one or both sides. A laminated stack is formed by stacking multiple core structures with intervening prepreg and then laminating the stack. A via is then formed by drilling a hole through the laminated stack and plating the wall of the hole with electrically conductive material, such as copper. The resulting plating interconnects the conductive layers in the laminated stack.

In some applications, a conductive trace within the PCB is configured as a transmission line. In order to have faster signal transfer and less signal loss in microwave transmission, it is better to have the transmission line not surrounded by laminate resin within the PCB build up layers. In this case a cavity filled with air is created within the multilayer PCB. Common fabrication process is to pre-cut low flow prepreg at a cavity area and then control resin squeeze out during the lamination process. This process has disadvantages such as high cost of low flow prepreg, limited supply of low flow prepreg and difficulty in controlling resin squeeze out. Additionally, lamination accessories such as release film and conformal film are needed which also add cost. Release film provides a separation between a surface copper layer (conducting layer) in the lamination stack and the conformal film. Conformal film is a thermoplastic layer which softens under lamination temperature and conforms to the area with prepreg pre-cut. Further, lamination under high pressure and the impact of conformal film can result in increased panel distortion and it is difficult to achieve flat surface for fine line etching or even dielectric thickness across the panel to control impedance. A panel here refers to the finished product of the stack of laminate and prepreg after lamination. In order to solve these issues, a new manufacturing process for forming a cavity within a PCB is needed.

### SUMMARY OF THE INVENTION

Embodiments are directed to a PCB having multiple stacked layers laminated together. The laminated stack includes regular flow prepreg and includes an embedded cavity, the perimeter of which is formed by a photo definable, or photo imageable, polymer structure, such as a solder mask dam. The solder mask dam defines cavity dimensions and prevents prepreg resin flow into the cavity during lamination. In this process, there is no need to control resin squeeze out nor a limitation in prepreg selection. Further, without use of lamination accessories or high lamination pressure, panel distortion and surface flatness are improved. In some embodiments, select portions of an inner layer circuitry, referred to as inner core circuitry, are included on one or more interior surfaces of the cavity. Such inner core circuitry can be used as transmission lines having improved electrical propagation properties due to exposure to air within the cavity, as opposed to transmission lines covered by prepreg or other dielectric as in conventional PCB stack-ups. In other embodiments, the inner surfaces of the cavity, except for those of the solder mask dam, are covered by a conductive layer such that the cavity forms a waveguide. In still other embodiments, the inner surfaces of the cavity are void of conductive material. In such a configuration, the cavity can be used, for example, as a fluid conduit.

In an aspect, a printed circuit board is disclosed. The printed circuit board includes a laminated stack of a plurality of non-conductive layers and a plurality of conductive layers. The printed circuit board also includes a photo imageable polymer structure formed within the laminated stack, wherein the photo imageable structure forms a boundary within which a cavity is formed. In some embodiments, the photo imageable polymer structure comprises a photo imageable polymer layer coupled between a first layer and a second layer in the laminated stack, wherein the first layer comprises one of the plurality of non-conductive layers or one of the plurality of conductive layers and the second layer comprises another one of the plurality of non-conductive layers or another one of the plurality of conductive layers. In some embodiments, one of the plurality of non-conductive layers comprises a prepreg layer, and the prepreg layer is positioned laterally adjacent to the photo imageable polymer layer. In some embodiments, the photo imageable polymer structure prevents resin flow from the prepreg layer into the cavity during lamination of the printed circuit board. In some embodiments, the prepreg layer comprises a regular flow prepreg layer having resin flow greater than about 100 mil. In some embodiments, the photo imageable polymer structure comprises a first photo imageable polymer layer coupled to a first layer in the laminated stack, wherein the first layer comprises one of the plurality of non-conductive layers or one of the plurality of conductive layers, further wherein the photo imageable polymer structure further comprises a second photo imageable polymer layer coupled to a second layer in the laminated stack, wherein the second layer comprises another one of the plurality of non-conductive layers or another one of the plurality of conductive layers, further wherein the laminated stack further comprises a base material layer, and the base material layer is positioned between the first photo imageable polymer layer and the second photo imageable polymer layer. In some embodiments, one of the plurality of non-conductive layers comprises a first prepreg layer, wherein the first prepreg layer is positioned laterally adjacent to the first photo imageable polymer layer, further wherein another one of the plurality of non-conductive layers comprises a second prepreg layer, wherein the second prepreg layer is positioned laterally adjacent to the second photo imageable polymer layer, and the base material is positioned between the first prepreg layer and the second prepreg layer. In some embodiments, the photo imageable polymer structure comprises a solder mask dam. In some embodiments, each of the conductive layers is pattern etched. In some embodiments, the printed circuit board further comprises one or more plated through hole vias in the rigid printed circuit board portion. In some embodiments, all surfaces within the cavity comprise non-conductive material. In some embodiments, one or more surfaces within the cavity comprise a conductive trace. In some embodiments, the conductive trace comprises a transmission line.

In another aspect, a method of manufacturing a printed circuit board is disclosed. The method comprises forming an inner core structure having a first surface and forming a photo imageable polymer structure on the first surface of the inner core structure. The photo imageable polymer structure forms a boundary within which a cavity is formed. The method further comprises removing a section from a prepreg layer. The section forms a cut-out section through an entire thickness of the prepreg layer. The cut-out section has a perimeter that substantially matches a footprint of the boundary of the photo imageable polymer structure. The method further comprises forming a printed circuit board stack up. The printed circuit board stack up comprises the inner core structure, the prepreg layer positioned against the first surface of the inner core structure such that the photo imageable polymer structure fits within the cut-out section of the prepreg layer, and a non-conductive layer or a conductive layer positioned against the prepreg layer such that the cavity is formed within the printed circuit board stack up. The method further comprises laminating the printed circuit board stack up, thereby forming a laminated stack. In some embodiments, the method further comprises forming at least one plated through hole via in the laminated stack, wherein the at least one plated through hole via is not aligned within the inner core circuitry. In some embodiments, the method further comprises pattern etching the conductive layers in the laminated stack prior to forming the printed circuit board stack up. In some embodiments, forming the inner core structure comprises applying a first conductive layer on a first surface of a non-conductive layer and applying a second conductive layer on a second surface of the non-conductive layer. In some embodiments, the first conductive layer is pattern etched and the second conductive layer is pattern etched. In some embodiments, the one or more non-conductive layers comprise one or more regular flow prepreg layers. In some embodiments, laminating the printed circuit board stack up comprises applying a standard lamination pressure less than about 450 psi.

### BRIEF DESCRIPTION OF THE DRAWINGS

Several example embodiments are described with reference to the drawings, wherein like components are provided with like reference numerals. The example embodiments are intended to illustrate, but not to limit, the invention. The drawings include the following figures:

FIG. 1 illustrates a cut-out side view of a printed circuit board including an embedded cavity according to some embodiments.

FIGS. 2-9 illustrate various steps in the process used to manufacture a printed circuit board according to some embodiments.

### DETAILED DESCRIPTION OF THE EMBODIMENTS

Embodiments of the present application are directed to a printed circuit board. Those of ordinary skill in the art will realize that the following detailed description of the printed circuit board is illustrative only and is not intended to be in any way limiting. Other embodiments of the printed circuit board will readily suggest themselves to such skilled persons having the benefit of this disclosure.

Reference will now be made in detail to implementations of the printed circuit board as illustrated in the accompanying drawings. The same reference indicators will be used throughout the drawings and the following detailed description to refer to the same or like parts. In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application and business related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

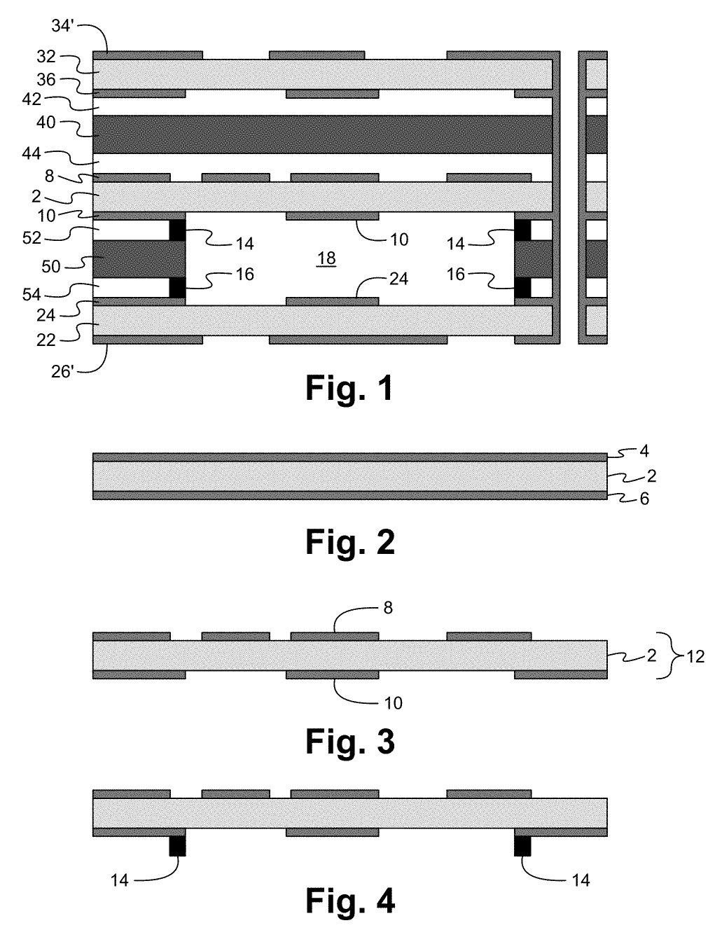

FIG. 1 illustrates a cut out side view of a printed circuit board including an embedded cavity according to some embodiments. The printed circuit board is a laminated stack having a plurality of non-conductive layers and a plurality of conductive layers. In the exemplary configuration shown in FIG. 1, the printed circuit board includes conductive layers 8, 10, 24, 26′, 34′ and 36 and non-conductive layers 2, 22, 32, 40, 42, 44, 50, 52 and 54. Each conductive layer is patterned to form electrically conductive interconnects. Although not shown in FIG. 1, electrically conductive vias can be formed in the laminated stack to electrically interconnect one or more conductive layers. A conductive layer can be formed, for example, from a copper foil or laminate, where a laminate includes a non-conductive layer such as base material and a conductive layer on one or both sides of non-conductive layer. In some embodiments, a conductive layer is representative of a multilayer buildup that can include many interspersed conductive and non-conductive layers.

Each non-conductive layer is made of a non-conductive, insulating layer, such as prepreg or base material. The prepreg used herein is a regular flow prepreg, which enables a regular pressure to be used during a subsequent lamination step. In the PCB industry, “low flow” prepreg, such as that described in the background, is a general term to describe prepreg with lower resin flow than “regular flow” prepreg. “Low flow” prepreg usually has resin flow that is less than 100 mil. “Regular flow” prepreg has resin flow that is greater than 100 mil. A base material is an organic or inorganic material used to support a pattern of conductor material. Base material and prepreg each include resin and glass cloth, but the resin in base material is already fully cured and as such does not flow during lamination and hence no need of solder mask dam. The resin in prepreg is only partially cured and therefore flows during lamination. A function of prepreg is to bind inner cores together during lamination. In the exemplary configuration shown in FIG. 1, there are three adjacent non-conductive layers 40, 42, 44. It is understood that this is merely a design choice and that one or more of the non-conductive layer 40, 42, 44 can be removed, or one or more additional adjacent non-conductive layers can be added.

Prior to stack-up and lamination of the printed circuit board layers, select portions of the non-conductive layers 50, 52 and 54 are cut out so that upon stack up the cut out portions are aligned to form a cavity 18. For those non-conductive layers 50, 52, 54 in which the cavity is formed and also that are made of prepreg, such non-conductive layers 52 and 54, a photo imageable polymer structure is used to prevent resin flow into the cavity 18 during the lamination step. In some embodiments, the photo imageable polymer structure includes a resin, a photo-activator or photo-initiator, and cross-linking agents that upon being subject to light become solid and remain attached to an underlying substrate. Any material not subject to light is easily washed away. In some embodiments, photolithography is used as a process for forming the photo imageable polymer structure. It is understood that other conventional processes can be used. A specific example of a photo imageable polymer structure is a solder mask dam. A solder mask, also referred to as a solder stop mask or solder resist, is a thin layer of polymer. Solder mask comes in different media. One type of solder mask is epoxy liquid that is silkscreened through a pattern onto an underlying substrate. Other types are liquid photo imageable solder mask (LPSM) inks and dry film photo imageable solder mask (DFSM). Subsequent reference is made to a “solder mask dam”, but it is understood that such teachings can generally be applied to other photo imageable polymer structures. In the exemplary configuration shown in FIG. 1, a solder mask dam 14 is formed adjacent to the prepreg non-conductive layer 52, and a solder mask dam 16 is formed adjacent to the prepreg non-conductive layer 54. The non-conductive layer 50 is positioned between the non-conductive layer 52 and the non-conductive layer 54, and also between the solder mask dam 14 and the solder mask dam 16. There are three adjacent non-conductive layers 50, 52, 54 shown in the exemplary configuration of FIG. 1. It is understood that this is merely a design choice and that one or more of the non-conductive layer 50, 52, 54 can be removed, or one or more additional adjacent non-conductive layers can be added. For example, the non-conductive layer 50 can be removed such that the non-conductive layers 52, 54 and the solder mask dams 14, 16 are adjacent to each other, or both the non-conductive layer 50 and one of the non-conductive layers 52 or 54, along with the corresponding solder dam mask 14 or 16, respectively, can be removed. As another example, one or more additional non-conductive layers made of base material can be stacked against the non-conductive layer 50. In this manner, any sized cavity can be formed by adjusting the number and/or thickness of the non-conductive layers having cut out portions that form the cavity.

In some embodiments, a cavity facing surface of the non-conductive layer 50 is aligned with a cavity facing surface of solder mask dams 14 and 16, as shown in FIG. 1, to form a planar surface. In other embodiments, the non-conductive layer 50 extends further into the cavity 18 than the solder mask dams 14, 16. In still other embodiments, the solder mask dams 14 and 16 are not aligned with each other, where one solder mask dam extends further into the cavity than the other solder mask dam.

The solder mask dams 14, 16 form an outer perimeter of the cavity 18. As such, a shape of the cavity can be formed by a shape of the solder mask dams and cut out portions in the corresponding non-conductive layers. If the solder mask dam is viewed from a top down perspective (not shown), the solder mask dam is enclosed and can be shaped as desired, for example as a rectangle or a circle.

In the exemplary configuration shown in FIG. 1, the electrically conductive interconnects formed on the conductive layer 10 includes a portion, referred to as inner core circuitry 10, that is within the cavity 18. Similarly, the electrically conductive interconnects formed on the conductive layer 24 includes a portion, referred to as inner core circuitry 24, that is also within the cavity 18. In some embodiments, the inner core circuitry 10, 24 within the cavity 18 are used as transmission lines. Since the inner core circuitry 10, 24 is not embedded in prepreg or other dielectric, and instead are exposed to air within the cavity, the electrical propagation properties are improved. In other embodiments, the entire conductive layer 10 within the cavity 18 is maintained as well as the entire conductive layer 24 within the cavity 18 such that the cavity forms a waveguide. In still other embodiments, the inner surfaces of the cavity are void of conductive material. In such a configuration, the cavity can be used, for example, as a fluid conduit.

FIGS. 2-9 illustrate various steps in the process used to manufacture a printed circuit board according to some embodiments. The printed circuit board manufactured using the various steps shown in FIGS. 2-9 is similar to and shares features of the printed circuit board and constituent layers shown in FIG. 1. Each of the FIGS. 2-9 illustrate a cut out side view of the printed circuit board according to the various process steps. In FIG. 2, an exemplary inner core structure is shown. The inner core structure is a metal clad structure including the non-conductive layer 2 and conductive layers 4, 6 formed on both opposing surfaces. It is understood that an alternative inner core structure can be used which includes a conductive layer on only one surface of the non-conductive layer.

In FIG. 3, the conductive layers 4 and 6 are selectively pattern etched to form inner core circuitry 8 and 10, respectively. Select portions of the inner core circuitry 10 are to be positioned within the embedded cavity. Alternatively, the conductive layers 4, 6 are already pattern etched during fabrication of the inner core structure in FIG. 2. It is understood that FIG. 2-9 only show a portion of the printed circuit board and in particular only show a portion of the inner core structure. Additional interconnects and circuitry may be formed on portions of the inner core structure not shown in FIGS. 2-9. The non-conductive layer 2 and the inner core circuitry 8, 10 form inner core structure 12.

In FIG. 4, the solder mask dam 14 is formed on the inner core structure 12. In some embodiments, the solder mask dam is formed on a conductive layer of the inner core structure, as shown in FIG. 4. In other embodiments, the solder dam mask is formed on a non-conductive layer of the inner core structure. As described above, the solder dam mask 14 can be any other type of photo imageable polymer structure formed using conventional photo imageable techniques.

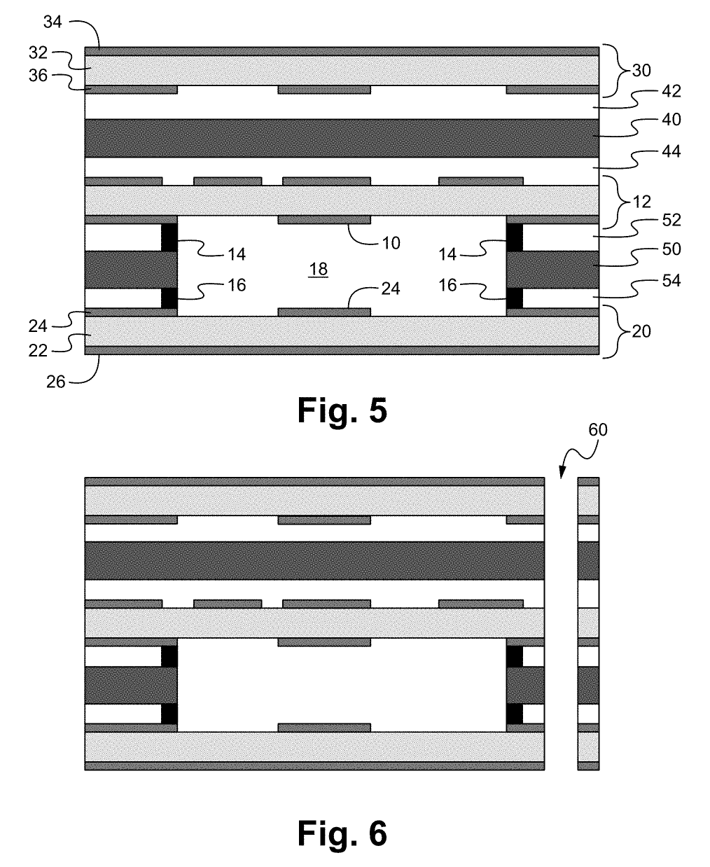

In FIG. 5, additional core structures are fabricated. The additional core structures can be similar to the inner core structure 12 of FIG. 3 with the conductive layers pattern etched accordingly. In most instances, the additional core structures are made using a non-conductive base material. In the exemplary configuration shown in FIG. 5, two additional core structures 20 and 30 are included. Depending on the configuration of the cavity, one of the additional core structures can also include a solder dam mask. In the exemplary configuration shown in FIG. 5, core structure 20 is fabricated and a solder dam mask 16 is formed on the core structure 20. The core structure 20 is a metal clad structure including a non-conductive layer 22 and conductive layers 24, 26 formed on both opposing surfaces. The conductive layer 24 is selectively pattern etched, where a portion of the selectively pattern etched conductive layer forms inner core circuitry 24 that is to be positioned within the embedded cavity. The core structure 30 is a metal clad structure including a non-conductive layer 32 and conductive layers 34, 36 formed on both opposing surfaces. The conductive layer 36 is selectively pattern etched. It is understood that alternatively configured core structures can be used which include a conductive layer on only one surface of the non-conductive layer.

The inner core structure 12 with solder dam mask 14, the core structure 20 with solder dam mask 16 and the core structure 30 are stacked with intervening non-conductive layers, such as regular flow prepreg layers 42, 44, 52 and 54 and base material non-conductive layers 40 and 50. Corresponding portions of the non-conductive layers 50, 52, 54 are cut out to form the cavity 18. As described above, the dimensions of the cavity 18 are determined by the thicknesses and numbers of non-conductive layers having cut out portions that form the cavity, as well as the position, shape and alignment of the solder dam masks. A solder dam mask is laterally aligned with each prepreg layer so as to prevent resin flow from the prepreg into the cavity. In the exemplary configuration shown in FIG. 5, the side walls of the cavity are formed by two solder mask dams 14, 16 and the non-conducting layer 50 made of base material. It is understood that additional base material non-conducting layers can be added as side walls to the cavity. Alternatively, the cavity may not include any base material non-conducting layers, in which case the cavity side walls are made entirely of solder dam mask. In this alternative configuration, the thickness of the solder dam mask is dependent on a thickness of the laterally adjacent prepreg non-conductive layer(s).

A single lamination step using standard lamination pressure results in the laminated stack shown in FIG. 5. Any conventional lamination technique can be used. As used herein, standard lamination pressure refers to the lamination pressure used with “regular flow” prepreg. With “regular flow” prepreg, lamination pressure is less than about 450 psi. With “low flow” prepreg, lamination pressure is more than about 450 psi.

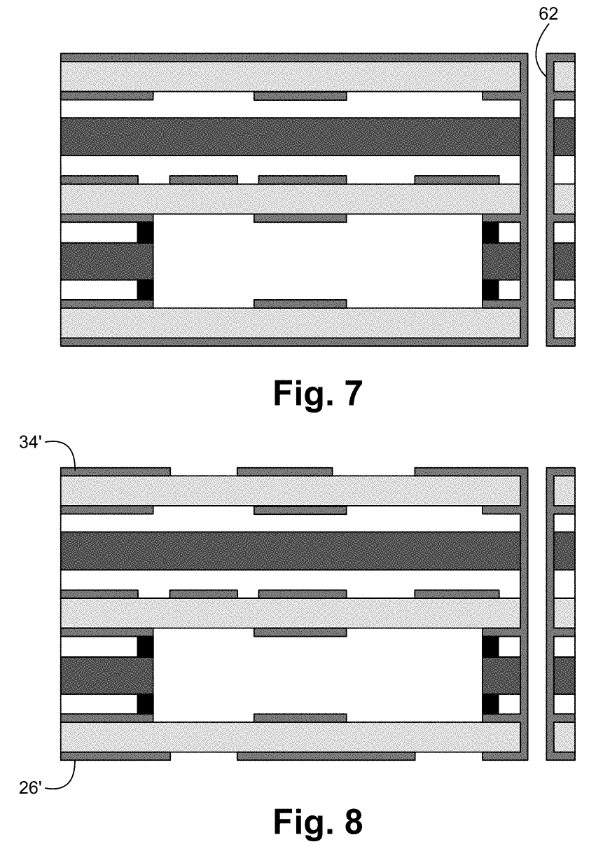

In FIG. 6, selective holes are drilled through the laminated stack of FIG. 5 to form vias, such as via 60. Vias are formed in those portions of the printed circuit board not corresponding to a cavity.

In FIG. 7, a desmear process is performed to remove residue, such as residual particles from the drilling of via 60. Next, an electroless plating process is performed to form plating 62 on the side walls of the via 60. In some embodiments, copper is used as the plating material. It is understood that other plating materials can be used. The plating 62 forms an interconnect with various conductive layers in the stack.

In FIG. 8, an outer conductive layer etching process is performed. The additional conductive layers 34 and 26 on the top and bottom, respectively, of the laminated stack are pattern etched to form patterned conductive layers 34′ and 26′.

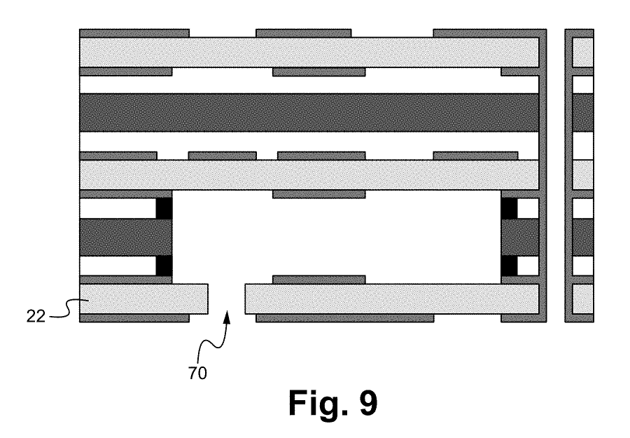

In FIG. 9, an optional step is performed where a hole is drilled into the cavity to enable degassing. In the exemplary configuration of FIG. 9, a hole 70 is drilled into an exposed portion of non-conductive layer 22.

It is understood that the various structural configurations and the position of the embedded cavity shown in the embodiments of FIGS. 2-9 can be interchanged according to a specific application and application requirement.

The printed circuit board and manufacturing processes described herein provided numerous advantages. The printed circuit board having a solder mask dam to form an embedded cavity is formed using regular flow prepreg. In prior art printed circuit boards, a PCB having an embedded cavity is formed using low flow prepreg as well as lamination accessories such as release film and conformal film. Use of low flow prepreg is needed to control squeeze out during lamination. However, since low flow prepreg is used, a greater lamination pressure is required which results in surface ripple on the PCB exterior surfaces. Under high pressure the underlying topography of the inner layer circuitry is reflected on the surface resulting in the irregular, or rippled, surface. In the present application, there is no need to control resin squeeze out, there is no limitation in prepreg selection, and there is no need of lamination accessories or high lamination pressure, which results in a flat exterior surfaces. The present process improves board flatness that solves impedance control issues and improves reliability of surface mounted component connections. Yield of fine line 2/2 mil etching and solder mask fine line imaging is also improved because of the flat exterior surfaces. Without use of lamination accessories and with yield improvement, the process of the present application saves running cost dramatically. Higher pressure lamination as used in conventional processes leads to expansion in the X-Y plane of the PCB. Such lateral expansion moves surface contact pads relative to their designed positions. The present process uses standard lamination pressure and therefore reduces lateral expansion. Such dimensional control is becoming more and more significant with smaller and smaller pitch components to be surface mounted.

The present application has been described in terms of specific embodiments incorporating details to facilitate the understanding of the principles of construction and operation of the printed circuit board. Many of the components shown and described in the various figures can be interchanged to achieve the results necessary, and this description should be read to encompass such interchange as well. As such, references herein to specific embodiments and details thereof are not intended to limit the scope of the claims appended hereto. It will be apparent to those skilled in the art that modifications can be made to the embodiments chosen for illustration without departing from the spirit and scope of the application.

What is claimed is:

1. A printed circuit board comprising:
a. a laminated stack of a plurality of non-conductive layers and a plurality of conductive layers; and
b. a photo imageable polymer structure formed within the laminated stack, wherein the photo imageable structure forms a boundary within which a cavity is formed.

2. The printed circuit board of claim 1 wherein the photo imageable polymer structure comprises a photo imageable polymer layer coupled between a first layer and a second layer in the laminated stack, wherein the first layer comprises one of the plurality of non-conductive layers or one of the plurality of conductive layers and the second layer comprises another one of the plurality of non-conductive layers or another one of the plurality of conductive layers.

3. The printed circuit board of claim 2 wherein one of the plurality of non-conductive layers comprises a prepreg layer, and the prepreg layer is positioned laterally adjacent to the photo imageable polymer layer.

4. The printed circuit board of claim 3 wherein the photo imageable polymer structure prevents resin flow from the prepreg layer into the cavity during lamination of the printed circuit board.

5. The printed circuit board of claim 3 wherein the prepreg layer comprises a regular flow prepreg layer having resin flow greater than about 100 mil.

6. The printed circuit board of claim 1 wherein the photo imageable polymer structure comprises a first photo imageable polymer layer coupled to a first layer in the laminated stack, wherein the first layer comprises one of the plurality of non-conductive layers or one of the plurality of conductive layers, further wherein the photo imageable polymer structure further comprises a second photo imageable polymer layer coupled to a second layer in the laminated stack, wherein the second layer comprises another one of the plurality of non-conductive layers or another one of the plurality of conductive layers, further wherein the laminated stack further comprises a base material layer, and the base material layer is positioned between the first photo imageable polymer layer and the second photo imageable polymer layer.

7. The printed circuit board of claim 6 wherein one of the plurality of non-conductive layers comprises a first prepreg layer, wherein the first prepreg layer is positioned laterally adjacent to the first photo imageable polymer layer, further wherein another one of the plurality of non-conductive layers comprises a second prepreg layer, wherein the second prepreg layer is positioned laterally adjacent to the second photo imageable polymer layer, and the base material is positioned between the first prepreg layer and the second prepreg layer.

8. The printed circuit board of claim 1 wherein the photo imageable polymer structure comprises a solder mask dam.

9. The printed circuit board of claim 1 wherein each of the conductive layers is pattern etched.

10. The printed circuit board of claim 1 further comprising one or more plated through hole vias in the rigid printed circuit board portion.

11. The printed circuit board of claim 1 wherein all surfaces within the cavity comprise non-conductive material.

12. The printed circuit board of claim 1 wherein one or more surfaces within the cavity comprise a conductive trace.

13. The printed circuit board of claim 12 wherein the conductive trace comprises a transmission line.

14. A method of manufacturing a printed circuit board comprising:
a. forming an inner core structure having a first surface;
b. forming a photo imageable polymer structure on the first surface of the inner core structure, wherein the photo imageable polymer structure forms a boundary within which a cavity is formed;
c. removing a section from a prepreg layer, wherein the section forms a cut-out section through an entire thickness of the prepreg layer, and the cut-out section has a perimeter that substantially matches a footprint of the boundary of the photo imageable polymer structure;
c. forming a printed circuit board stack up, wherein the printed circuit board stack up comprises the inner core structure, the prepreg layer positioned against the first surface of the inner core structure such that the photo imageable polymer structure fits within the cut-out section of the prepreg layer, and a non-conductive layer or a conductive layer positioned against the prepreg layer such that the cavity is formed within the printed circuit board stack up; and
d. laminating the printed circuit board stack up, thereby forming a laminated stack;

15. The method of claim 14 further comprising forming at least one plated through hole via in the laminated stack, wherein the at least one plated through hole via is not aligned within the inner core circuitry.

16. The method of claim 14 further comprising pattern etching the conductive layers in the laminated stack prior to forming the printed circuit board stack up.

17. The method of claim 14 wherein forming the inner core structure comprises applying a first conductive layer on a first surface of a non-conductive layer and applying a second conductive layer on a second surface of the non-conductive layer.

18. The method of claim 17 wherein the first conductive layer is pattern etched and the second conductive layer is pattern etched.

19. The method of claim 14 wherein the one or more non-conductive layers comprise one or more regular flow prepreg layers.

20. The method of claim 19 wherein laminating the printed circuit board stack up comprises applying a standard lamination pressure less than about 450 psi.
